(19) United States
(12) Patent Application Publication
(10) Pub. No.: US 2021/0217923 A1
(43) Pub. Date: Jul. 15, 2021

(54) Transparent Electrode for Sensor and the Fabrication Method Thereof

(71) Applicants: SK Innovation Co., Ltd., Seoul (KR); Industry-Academic Cooperation Foundation, Yonsei University, Seoul (KR)

(72) Inventors: Jun Hyung Kim, Daejeon (KR); Sang Yoon Ji, Daejeon (KR); Jang-Ung Park, Seoul (KR)

(21) Appl. No.: 17/147,815

(22) Filed: Jan. 13, 2021

(30) Foreign Application Priority Data
Jan. 14, 2020 (KR) 10-2020-0004839

(51) Int. Cl. H01L 31/18; D01D 5/00; B22F 3/10; H01L 31/0224; B22F 1/00

(52) U.S. Cl. CPC H01L 31/1884; D01D 5/0084; B22F 3/10; B82Y 30/00; B22F 1/0096; B22F 1/0025; D01D 5/003; H01L 31/022491

(57) ABSTRACT

Provided is a method of producing a transparent electrode including: a) applying a first dispersion containing a metal nanowire on a substrate to form a nanowire network; b) electrospinning a second dispersion containing metal nanoparticles on the nanowire network to form a fiber-nanowire network in which a metallic fiber of the metal nanoparticles being agglomerated is incorporated into the nanowire network; and c) sintering the fiber-nanowire network.

### CROSS-REFERENCE TO RELATED APPLICATION

This application claims priority to Korean Patent Application No. 10-2020-0004839 filed Jan. 14, 2020, the disclosure of which is hereby incorporated by reference in its entirety.

### BACKGROUND OF THE INVENTION

### Field of the Invention

The following disclosure relates to a transparent electrode for a sensor and a method of producing the same, and more particularly, to a transparent electrode appropriate for a flexible or rollable electronic device and a method of producing the same.

### Description of Related Art

It is difficult for a traditional transparent electrode based on a transparent conductive oxide such as ITO to have a large area, and the traditional transparent electrode should undergo an expensive complicated process such as vacuum deposition, has greatly decreased electrical properties upon miniaturization, and has no flexibility so that it is difficult to use the electrode in a flexible fine device.

In order to improve the problems of the conventional transparent electrode, studies to use nanomaterials such as carbon nanotubes, graphene, and metal nanowires to develop a flexible transparent electrode, have been continuously conducted.

However, even when the nanomaterials are used, as a line width of the electrode is finer, a resistance of the electrode is increased by a contact resistance between nanomaterials, and also, when a large amount of current flows, the nanomaterials are damaged by electromigration or the like.

In order to overcome the problems of the nanomaterial, a technology of a hybrid structure which is formed by combining a first nanostructure having a first diameter and a second nanostructure having a second diameter which is smaller than the first diameter with each other (Korean Patent Registration No. 1863818) has been suggested. The suggested composite electrode technology shows significantly excellent electrical properties even when an electrode has a fine line width, but when the electrical properties are improved, transparency is lowered, and the electrical properties are rapidly deteriorated by repetitive bending, thereby making it difficult to use the electrode in an actual flexible or rollable device.

### RELATED ART DOCUMENTS

### Patent Documents

(Patent Document 0001) Korean Patent Registration No. 1863818

### SUMMARY OF THE INVENTION

An embodiment of the present invention is to provide a transparent electrode which stably maintains electrical properties even with repeated physical deformation and has a low sheet resistance and a high transparency, and a method of producing the same.

Another embodiment of the present invention is directed to providing a transparent electrode having excellent electrical, optical, and mechanical properties by a commercializable simple process, and a method of producing the same.

In one general aspect, a method of producing a transparent electrode includes: a) applying a first dispersion containing a metal nanowire on a substrate to form a nanowire network; b) electrospinning a second dispersion containing metal nanoparticles on the nanowire network to form a fiber-nanowire network in which a metallic fiber of the metal nanoparticles being agglomerated is incorporated into the nanowire network; and c) sintering the fiber-nanowire network.

In the production method according to an exemplary embodiment of the present invention, the sintering may be performed by a photonic sintering or a heat treatment.

In the production method according to an exemplary embodiment of the present invention, in step b), a coaxial double nozzle including an inner nozzle and an outer nozzle surrounding the inner nozzle may be used at the time of electrospinning to spin the second dispersion through the inner nozzle and to spin a polymer solution through the outer nozzle, thereby forming a composite fiber in which the metallic fiber is wrapped by a polymer sheath.

The production method according to an exemplary embodiment of the present invention may further include removing the polymer sheath from the composite fiber after the electrospinning of step b).

In the production method according to an exemplary embodiment of the present invention, the metallic fiber may be converted into a conductive fiber by the sintering of step c), and fusion may be performed between the nanowire and the fiber of the fiber-nanowire network and between the nanowires.

In the production method according to an exemplary embodiment of the present invention, a nanowire fill factor which is a ratio of an area covered by the metal nanowire may be to 11%, a fiber fill factor which is a ratio of an area covered by the metallic fiber may be 3 to 10%, and a network fill factor which is a ratio of an area covered by the metal nanowire and the metallic fire network may be 9 to 13%, with respect to an area of the substrate in step a).

In the production method according to an exemplary embodiment of the present invention, the heat treatment may be performed at 150 to 250° C.

In the production method according to an exemplary embodiment of the present invention, the photonic sintering may be performed by pulsed white light irradiation having an intensity of 800 to 1600 J/cm².

In the production method according to an exemplary embodiment of the present invention, a ratio of a diameter of the metal nanowire to a diameter of the metallic fiber may be 10 to 1000.

In the production method according to an exemplary embodiment of the present invention, the metal nanowire and the metal nanoparticles of the metallic fiber may include silver (Ag), gold (Au), aluminum (Al), copper (Cu), chromium (Cr), nickel (Ni), iron (Fe), or an alloy thereof, respectively.

The present invention includes a transparent electrode produced by the production method described above.

In another general aspect, a transparent electrode includes: a transparent film; and a conductive network, in which a metal nanowire and a metallic conductive fiber are mixed, positioned on the transparent film, wherein a nanowire fill factor which is a ratio of an area covered by the metal nanowire is 3 to 11%, a fiber fill factor which is a ratio of an area covered by the metallic conductive fiber is 3 to 10%, and a conductive network fill factor which is a ratio of a sum of an area covered by the metal nanowire and an area covered by the conductive fiber is 9 to 13%, in the transparent film.

In the transparent electrode according to an exemplary embodiment of the present invention, the transparent electrode may have a light transmittance of 90% or more and a sheet resistance of 1.9 Ω/sq. or less.

In the transparent electrode according to an exemplary embodiment of the present invention, the transparent electrode may have a sheet resistant increase rate of 5% or less, when a bending test is performed 100,000 times with a bending radius of 3 mm.

In still another general aspect, a device includes the transparent electrode described above.

Other features and aspects will be apparent from the following detailed description, the drawings, and the claims.

### BRIEF DESCRIPTION OF THE DRAWINGS

FIG. 1 is a scanning electron microscope image in which a conductive network produced according to an exemplary embodiment of the present invention is observed.

FIG. 2 is a scanning electron microscope image in which a network part between nanowires in a conductive network produced according to an exemplary embodiment of the present invention is observed.

FIG. 3 is a drawing illustrating a sheet resistance depending on the number of bends measured by performing a bending test 100,000 times with a curvature radius of 3 mm for the produced transparent electrode.

### DESCRIPTION OF THE INVENTION

Hereinafter, the transparent electrode of the present invention and a method of producing the same will be described in detail with reference to the accompanying drawings. The drawings to be provided below are provided by way of example so that the idea of the present invention can be sufficiently transferred to a person skilled in the art to which the present invention pertains. Therefore, the present invention is not limited to the drawings provided below but may be embodied in many different forms, and the drawings suggested below may be exaggerated in order to clear the spirit of the present invention. Technical terms and scientific terms used herein have the general meaning understood by those skilled in the art to which the present invention pertains unless otherwise defined, and a description for the known function and configuration which may unnecessarily obscure the gist of the present invention will be omitted in the following description and the accompanying drawings.

In addition, the singular form used in the specification and claims appended thereto may be intended to also include a plural form, unless otherwise indicated in the context.

In the present specification and the appended claims, the terms such as “first” and “second” are not used in a limited meaning but used for the purpose of distinguishing one constitutional element from other constitutional elements.

In the present specification and the appended claims, the terms such as “comprise” or “have” means that there is a characteristic or a constitutional element described in the specification, and as long as it is not particularly limited, a possibility of adding one or more other characteristics or constitutional elements is not excluded in advance.

In the present specification and the appended claims, when a portion such as a film (layer), a region, and a constitutional element are present on another portion, not only a case in which the portion is in contact with and directly on another portion but also a case in which other films (layers), other regions, and other constitutional elements are interposed between the portions is included.

The method of producing a transparent electrode according to the present invention includes: a) applying a first dispersion containing a metal nanowire on a substrate to form a nanowire network; b) electrospinning a second dispersion containing metal nanoparticles on the nanowire network to form a fiber-nanowire network in which a metallic fiber of the metal nanoparticles being agglomerated is incorporated into the nanowire network; and c) sintering the fiber-nanowire network.

As described above, in the method of producing a transparent electrode according to the present invention, the metal nanowire network is first formed on a substrate, the second dispersion is electrospun on the metal nanowire network to incorporate a network of the metallic fiber into the metal nanowire network to form the fiber-nanowire network, and the produced fiber-nanowire network is sintered to produce the transparent electrode. By the method, a transparent electrode having both a very high transparency and significantly excellent electrical properties may be produced, and also, a flexible electrode which hardly causes deterioration of electrical properties even with repeated deformation while having excellent flexibility may be produced. Here, a network may refer to a structure which is randomly in contact with the nanowire or the fiber and in which a continuous path between two arbitrary points is provided.

In a specific example, the first dispersion may contain a metal nanowire and a first dispersion medium. The metal nanowire may be silver (Ag), gold (Au), aluminum (Al), copper (Cu), chromium (Cr), nickel (Ni), iron (Fe), or an alloy thereof, but is not limited thereto. Even when a microelectrode having a fine pitch (width) of an order of several micrometers is implemented, the metal nanowire may have an average diameter of about 5 to 100 nm and an aspect ratio of 100 to 10,000, so that a stable network may be formed by the nanowire, but the present invention is not necessarily limited thereto.

Any solvent may be used as the first dispersion medium, as long as the metal nanowire is easily dispersed therein and the solvent may be removed by volatilization at a low temperature. As a specific example, the first dispersion medium may include 2-butoxyethyl acetate, propylene glycol monomethyl ether acetate, diethylene glycol monoethyl ether acetate, ethylene glycol butyl ether, cyclohexanone, cyclohexanol, 2-ethoxyethyl acetate, ethylene glycol diacetate, terpineol, isobutyl alcohol, water, or a mixed solution thereof, but the present invention is not limited to these kinds of the first dispersion medium, of course.

The first dispersion may contain 0.01 to 70 parts by weight of the metal nanowire, based on 100 parts by weight of the first dispersion medium, but the present invention is not limited to the content of the metal nanowire in the first dispersion, of course.

If necessary, the first dispersion may further include additives commonly used in the nanowire dispersion in a nanowire-based transparent electrode field, such as a dispersant, an anticorrosive agent, and a binder, which improve dispersibility of the nanowire, in addition to the metal nanowire and the first dispersion medium, of course.

Application of the first dispersion may be performed using any method which has been used for producing a film or a pattern by applying and drying a liquid or disperse phase, in a semiconductor or display manufacturing field. As an example, application of the first dispersion may use various methods such as coating, spraying, and printing, and as a specific example, spin coating; screen printing; inkjet printing; bar-coating; gravure-coating; blade coating; roll-coating; slot die; electrospinning; spray spinning; and the like may be included, but the present invention is not limited thereto.

In step a), after performing application of the first dispersion, if necessary, drying may be further performed. Drying may be performed by natural drying, irradiation of light including an infrared light, hot air drying, a method of using a dried air flow, heating using a heat source, and the like. However, electrospinning in step b) may be performed without a separate drying step.

Step b) is a step of incorporating the metallic fiber into the nanowire network using electrospinning to form a fiber-nanowire network. Here, unless otherwise limited, the metallic fiber refers to an agglomerate in a fiber form, and has too high of a resistance to be substantially used as an electrode. As described later, metal nanoparticles agglomerated are fused together by the sintering in step c), whereby the metallic fiber may be converted into a conductive fiber having conductivity. Thus, the metallic fiber and the conductive fiber should be clearly distinguished.

Step b) may include a step of using a coaxial double nozzle including an inner nozzle and an outer nozzle surrounding the inner nozzle, and spinning the second dispersion containing the metal nanoparticles through the inner nozzle and spinning the polymer solution through the outer nozzle to form a composite fiber in which the metallic fiber is wrapped in a polymer sheath.

A polymer is spun from the outer nozzle and wraps the metal nanoparticles spun through the inner nozzle, so that the metal nanoparticles may not be spun widely and the shape of the fiber may be formed and maintained.

The metal nanoparticles of the second dispersion may be, independently of the metal nanowire, silver (Ag), gold (Au), aluminum (Al), copper (Cu), chromium (Cr), nickel (Ni), iron (Fe), or an alloy thereof, but are not limited thereto. However, it is preferred that the metal nanoparticle are the same metal as the metal of the metal nanowire so that at the time of the photonic sintering in step c), the metal nanoparticles are fused together and the metallic fiber is converted into the conductive fiber, and simultaneously, uniformly and stably, contact sites between the conductive fiber (or the metallic fiber in the middle of being converted into the conductive fiber) and the metal nanowire and between the metal nanowire and the metal nanowire are fused together.

The metal nanoparticles may only have a size to be easily spun through the inner nozzle. As an example, the metal nanoparticles may have a diameter of about 5 nm to 200 nm. However, it is preferred that the metal nanoparticles have a diameter of about 5 to 100 nm, specifically 5 to 60 nm, and more specifically 20 to 60 nm, so that at the time of the sintering in step c), a high sintering driving force may be provided by the metal nanoparticles.

A content of the metal nanoparticles in the second dispersion may be 60 to 85 wt %, but is not limited thereto. A dispersion medium of the second dispersion may be an alkane-based solvent, an aromatic solvent, an ether-based solvent, an alkyl halide, an ester-based solvent, an aldehyde-based solvent, a ketone-based solvent, an amine-based solvent, an alcohol-based solvent, an amide-based solvent, water, a mixed solvent thereof, or the like. As a substantial example, the dispersion medium of the second dispersion may be methanol, acetone, tetrahydrofuran, toluene, diethyl ether, dimethyl formamide, chloroform, α-terpineol, or the like, but is not limited thereto.

The polymer of the polymer solution may be polyvinylpyrrolidone, polyvinylalcohol, polymethylmethacrylate, polydimethylsiloxane, polyurethane, polyetherurethane, cellulose acetate, cellulose acetate butylate, cellulose acetate propionate, polymethylacrylate, polyvinylacetate, polyacrylonitrile, polyfurfuryl alcohol, polystyrene, polyethylene oxide, polypropylene oxide, polycarbonate, polyvinyl chloride, polycaprolactone, polyvinyl fluoride, polyamide, a copolymer thereof, or the like, but any polymer is possible as long as it is an easily electrospinnable material. A solvent of the polymer solution may be a liquid material which may dissolve the polymer and be easily removed by volatilization, such as an alkane-based solvent, an aromatic-based solvent, an ether-based alkyl halide, an ester-based solvent, an aldehyde-based solvent, a ketone-based solvent, an amine-based solvent, an alcohol-based solvent, an amide-based solvent, water, or a mixed solvent thereof. A concentration of the polymer in the polymer solution may be about 20 to 80 wt %.

The diameter of the metallic fiber may be controlled by a diameter of the inner nozzle of the coaxial double nozzle, and a thickness of the polymer sheath may be controlled by a distance between the inner nozzle and the outer nozzle.

The metallic fiber which is converted into the conductive fiber by step c) may form a main current move path by a low resistance as compared with the nanowire, and a relatively fine nanowire as compared with the fiber may serve to connect the fiber and the fiber when the main current move path by the fiber is disconnected by electrode micronization.

Thus, the metallic fiber may have a diameter (inner nozzle diameter) of an order of about 10² nm to 10¹ μm, specifically an order of about 10° μm to 10¹ μm, so that the main current move path may be provided by the low resistance compared with the nanowire. As a substantial example, the metallic fiber may have a diameter of about 500 nm to 10 μm, or 1 μm to 5 μm. In addition, a ratio of the diameter of the metallic fiber to the diameter of the metal nanowire may be 10 to 1000, specifically 50 to 1000, but is not necessarily limited thereto. Here, since the metallic fiber (or composite fiber) is formed by electrospinning, a length of the metallic fiber (or composite fiber) is not substantially limited. As an example, the metallic fiber (or composite fiber) may have a length of several to several to tens of centimeters, and as an extreme example, the metallic fiber (or composite fiber) introduced to the nanowire network may be a single fiber which is randomly bent and interwound.

The thickness of the polymer sheath (a distance between the inner nozzle and the outer nozzle) may be a thickness to stably restrain the metal nanoparticles spun from the inner nozzle in a fiber form. As an example, the thickness of the polymer sheath may be about 0.1 to 1 D based on the diameter (D) of the metallic fiber, but is not limited thereto.

In a specific example, at the time of electrospinning for forming the metallic fiber, a discharge rate of the nozzle may be about 0.1 to 1.0 ml/h, and a voltage may be about 5 to 10 kV, but they are not limited thereto.

As described above, a composite fiber having a core-sheath structure in which the metallic fiber is the core and the polymer is the sheath may be introduced to the nanowire network by the electrospinning.

After the electrospinning of step b), specifically, after the electrospinning of step b) and before the sintering of step c), step b2) of removing the polymer sheath from the composite fiber may be further performed. The polymer sheath may be removed using wet removal using an organic solvent, dry removal using reactive ion etching (RIE), thermal decomposition removal using a heat treatment at about 150 to 200° C. in the air, a combination thereof, or the like. By removing the polymer sheath from the composite fiber using an organic solvent, reactive ion etching, or the fiber-nanowire network in which the metal nanoparticle(s) agglomerated in a fiber form with the metal nanowire is (are) in contact with each other may be produced.

At the time of nanowire network formation of step a) and metallic fiber formation of step b), in the substrate, a nanowire fill factor which is a ratio of an area covered by the metal nanowire (area covered by the nanowire/area of the substrate) may be 3 to 11% and a fiber fill factor which is a ratio of an area covered by the metallic fiber (area covered by the fiber/area of the substrate) may be 3 to 10%. In addition, both the nanowire fill factor and the fiber fill factor may be satisfied, and also a network fill factor which is a ratio of the sum of an area covered by the metal nanowire and an area covered by the metallic fiber (area covered by the fiber-nanowire network/area of the substrate) may be 9 to 13%, specifically 11 to 13%.

That is, at the time of the application of step a), the first dispersion may be applied so that the nanowire fill factor satisfies 3 to 11%, and at the time of the electrospinning of step b), the second dispersion is electrospun so that the fiber fill factor satisfies 3 to 10%, but the application of step a) and the electrospinning of step b) may be performed so that the fiber-nanowire network fill factor satisfies 9 to 13%.

The nanowire fill factor and the fiber fill factor, preferably, the nanowire fill factor, the fiber fill factor, and the fiber-nanowire network fill factor, satisfy the range described above, whereby the produced transparent electrode may have high transparency (light transmittance) while having excellent electrical conductivity.

Specifically, the nanowire fill factor may be 3 to 5%, the fiber fill factor may be 8 to 10%, and the network fill factor may be 11 to 13%. Otherwise, the nanowire fill factor may be 8 to 11%, the fiber fill factor may be 3 to 5%, and the network fill factor may be 11 to 13%. When the fill factor is satisfied, the transparent electrode produced in step c) may have a light transmittance of 90% or more, specifically 91% or more, and more specifically 92% or more, and together with the excellent optical properties, may also have excellent electrical properties of a sheet resistance of 1.9 Ω/sq. or less, specifically 1.8 Ω/sq. or less, and more specifically 1.7 Ω/sq. Here, the light transmittance may be measured in accordance with ASTM D 1003, and be a light transmittance based on a wavelength of 550 nm. In addition, experimentally, the sheet resistance may be measured using a 4-point probe. In addition, the sheet resistance may be an average value obtained by averaging the sheet resistance values measured at 5 or more random regions, specifically 5 to 50 random regions. In addition, experimentally, the nanowire or fiber fill factor may be a value measured for a sample in which the first dispersion is applied to the substrate in the same manner as in transparent electrode production to form the nanowire network alone or a sample in which the second dispersion is electrospun on the substrate (substrate on which the nanowire is not applied) in the same manner as in transparent electrode production and the polymer sheath is removed to form a fiber network alone. The network fill factor may be a value measured for a sample in which the first dispersion is applied to the substrate in the same manner as in transparent electrode production to form the nanowire network, the second dispersion is electrospun on the nanowire network, and the polymer sheath is removed to form the fiber-nanowire network. Measurement of each fill factor may be carried out by obtaining a microstructure observation image using a scanning electron microscope or the like, and then calculating an area of the fiber (fiber fill factor), an area of the nanowire (nanowire fill factor), or an area occupied by the fiber and the nanowire (network fill factor) in the entire area of the image. For easy calculation, the observation image may be converted to black/white, the nanowire or the fiber may be designated as black or white, of course, and the number of black or white pixels relative to the total number of image pixels may be used to calculate the covered area, of course. In addition, each fill factor may be an average value obtained by averaging each fill factor value measured at 5 or more random regions, specifically 5 to 50 random regions of each sample.

As described above, the fiber-nanowire network produced by step b) may be in the state of having a very high sintering driving force by the metal nanoparticles of the metallic fiber.

After step b), preferably after performing step b2), step c) of sintering the fiber-nanowire network may be performed.

By the sintering of step c), the metal nanoparticles which are agglomerated in a fiber form may be melted and bound and the metallic fiber may be converted into the conductive fiber, and also, fusion (binding) may be performed at a contact point between the fiber and the nanowire and the contact point of the nanowires.

The sintering may be performed by a photonic sintering or a heat treatment. Specifically, when the sintering of step c) is performed by a heat treatment, the heat treatment may be performed at a temperature of 150 to 250° C., specifically 200 to 220° C. When the sintering is performed by a photonic sintering, the photonic sintering may be performed by pulsed white light irradiation having an intensity of 800 to 1600 J/cm², specifically 1300 to 1600 J/cm². The white light may be a light in a band of 300-1000 nm and a pulse width may be 500 to 2000 μsec, specifically 1000 to 2000 μsec. The number of pulses irradiated in the photonic sintering may be 1 to 5, specifically 1 to 3, but is not limited thereto.

Advantageously, the sintering of step c) may be a photonic sintering. When the sintering is performed by a heat treatment, a laminate including the substrate positioned in a lower portion of the fiber-nanowire network should be heated as a whole, and thus, there is a risk of thermal damage occurring in the substrate and there is a limitation of using the substrate having appropriate thermal resistance. In addition, when the sintering is performed by a heat treatment, the heat treatment should be performed at a temperature as low as possible, and thus, a long-term heat treatment of several hours is required for achieving the sintering to obtain high electrical conductivity, thereby making it difficult to be used in a commercial process. Furthermore, according to the present invention, since the nanowire network is first formed and then the metallic fiber is incorporated into the nanowire network, the nanowire network should be also heat-treated with the metallic fiber at the time of a heat treatment, and the nanowire is unnecessarily heated at a high temperature for a long time for sintering the fiber so that the nanowire is broken, and thus, there is also a risk of thermal damage of the nanowire network.

However, in the case of the photonic sintering, since the sintering may be completed in a millisecond or second unit, the substrate layer may be free from thermal damage, and it is an extremely simple and inexpensive energy saving process, the photonic sintering has excellent commerciality as compared with the heat treatment. In addition, furthermore, according to the present invention, when the nanowire network is first formed, the metallic fiber is incorporated into the nanowire network, and then a photonic sintering is performed, since the nanowire is constrained by the metallic fiber, a decrease of contact points by distortion of the nanowire occurring in the photonic sintering may be effectively suppressed.

Unlike the present invention, when the second dispersion is electrospun on a substrate, the polymer sheath is removed, and the sintering is performed to form the conductive fiber network first, and then the metal nanowire is applied to introduce the metal nanowire to the conductive fiber network, the metal nanoparticles are in the state of being already sintered to lose most of a sintering driving force, and thus, there is a limitation that it is substantially difficult to fuse the metal nanowire and the conductive fiber. Substantially, in order to fuse the metal nanowire on the already sintered conductive fiber, higher heat or light energy than the energy required in the contact point between the nanowires is required, and thus, there is a risk that the nanowire is broken by partial melting of the metal nanowire so that the nanowire network is damaged.

In addition, unlike the present invention, when the second dispersion is electrospun on the substrate, the polymer sheath is removed to form the metallic fiber network, the metal nanowire is applied to introduce the metal nanowire to the metallic fiber network, and then the sintering is performed to convert the metallic fiber network into the conductive fiber network, there is a risk that electrical/mechanical properties of the electrode at the time of the photonic sintering are greatly deteriorated, thereby substantially not using the photonic sintering which is advantageous to a commercial process. Substantially, when the metal nanowire is introduced to the metallic fiber network and then a photonic sintering is performed, there is a risk that a metallic fiber part in a lower portion of a region where the contact points between the metal nanowires gather close together is incompletely converted into the conductive fiber. When the transparent electrode is deformed, stress may be concentrated in this completely converted region and the fiber may be broken to greatly deteriorate electrical properties.

However, according to the present invention, when the metal nanowire network is first formed on the substrate, the metallic fiber is introduced to the nanowire network, and then the nanowire network to which the metallic fiber is introduced (fiber-nanowire network) is sintered all together, the metallic fiber is entirely homogeneously sintered by the photonic sintering and converted into the conductive fiber, and simultaneously, stable and uniform fusion may be performed between the fiber and the nanowire and between the nanowires.

Thus, the transparent electrode produced according to the present invention may have extremely excellent physical/electrical properties to maintain a sheet resistance increase rate of 5% or less, even in a bending test of 100,000 times with a bending radius of 3 mm.

The present invention includes a transparent electrode produced by the production method described above.

The present invention provides a transparent electrode including a conductive network in which the conductive network of the metal nanowire and the metallic conductive fiber are mixed. Here, the metal nanowire corresponds to the metal nanowire described above in the production method, the metallic conductive fiber corresponds to the conductive fiber obtained by sintering the metallic fiber in step c) of the production method, and the conductive network corresponds to the network obtained by sintering the fiber-nanowire network by step c) in the production method. Thus, the transparent electrode includes all contents of the production method described above.

The transparent electrode according to the present invention includes: a transparent film; and a conductive network, in which a metal nanowire and a metallic conductive fiber are mixed, positioned on the transparent film, wherein a nanowire fill factor which is a ratio of an area covered by the metal nanowire is 4 to 11%, a conductive fiber fill factor which is a ratio of an area covered by the conductive fiber is 3 to 10%, and a conductive network fill factor which is a ratio of a sum of an area covered by the metal nanowire and an area covered by the conductive fiber is 9 to 13%, in the transparent film.

When the nanowire fill factor, the conductive fiber fill factor, and the conductive network fill factor described above are satisfied, the transparent electrode may have a light transmittance of 90% or more, and a sheet resistance of 1.9 Ω/sq. or less.

In the transparent electrode according to an exemplary embodiment, the nanowire fill factor may be 3 to 5%, the conductive fiber fill factor may be 8 to 10%, and the conductive network fill factor may be 11 to 13%. In the transparent electrode according to an exemplary embodiment, the nanowire fill factor may be 8 to 11%, the conductive fiber fill factor may be 3 to 5%, and the conductive network fill factor may be 11 to 13%. When the fill factor is satisfied, the transparent electrode may have a light transmittance of 90% or more, specifically 91% or more, and more specifically 92% or more, and together with the excellent optical properties, may also have excellent electrical properties of a sheet resistance of 1.9 Ω/sq. or less, specifically 1.8 Ω/sq. or less, and more specifically 1.7 Ω/sq. or less.

The transparent electrode according to an exemplary embodiment may have a sheet resistant increase rate of 5% or less, when a bending test is performed 100,000 times with a bending radius of 3 mm. The bending test may be performed with bending with a radius of 3 mm using a common two point bending tester, and the sample used in the bending test may have a length×a width of about 5 to 30 cm×5 to 30 cm. The transparent film may be appropriately selected considering the use of the transparent electrode, and as an example, may be glass; polyester-based films such as polyester naphthalate or polycarbonate; polyolefin-based film such as linear, branched, and cyclic polyolefin; polyvinyl-based films such as polyvinyl chloride, polyvinylidene chloride, polyvinyl acetal, polystyrene, and polyacryl; cellulose ester base films such as cellulose triacetate or cellulose acetate; polysulfone films such as polyethersulfone; polyimide films; or silicone films; and the like, but the present invention is not limited to those substrates, of course. The substrate may be in the form of a thin film, a film, or the like, but may have a shape appropriate for the use of a transparent conductor, of course. However, the transparent film may have a light transmittance to a light having a wavelength of 550 nm of 90% or more, specifically 93% or more, more specifically 95% or more, and more specifically 97% or more.

The present invention includes a transparent electrode produced by the production method described above and a display device including the transparent electrode described above.

As a specific example, the present invention includes a transparent electrode produced by the production method described above and a liquid crystal display including the transparent electrode described above.

As a specific example, the present invention includes a transparent electrode produced by the production method described above and a touch panel including the transparent electrode described above.

As a specific example, the present invention includes a transparent electrode produced by the production method described above and an electroluminescent device including the transparent electrode described above.

As a specific example, the present invention includes a transparent electrode produced by the production method described above and a photovoltaic cell including the transparent electrode described above.

As a specific example, the present invention includes a transparent electrode produced by the production method described above and an anti-static layer including the transparent electrode described above.

As a specific example, the present invention includes a transparent electrode produced by the production method described above and a fingerprint recognition sensor including the transparent electrode described above.

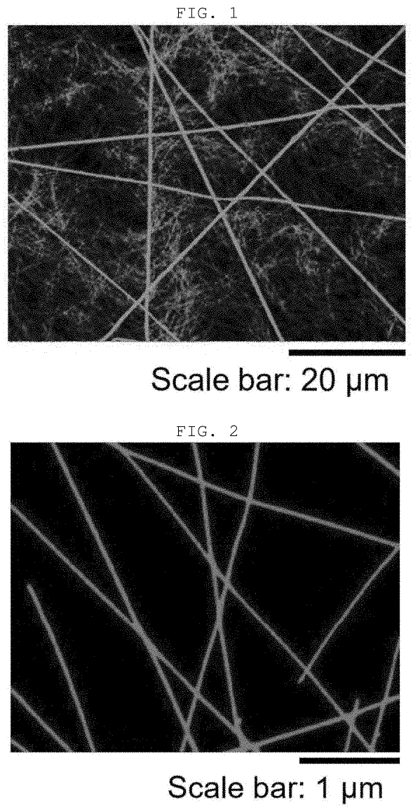

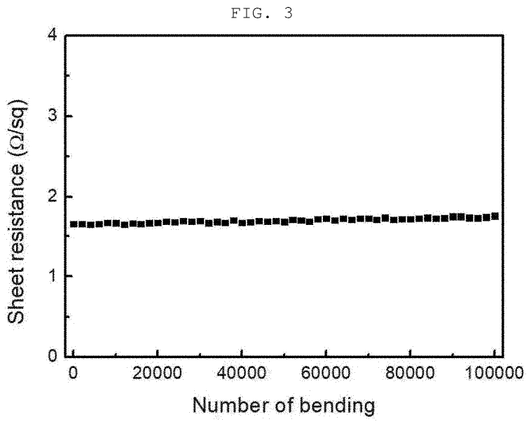

FIG. 1 is a scanning microscope image in which the conductive network produced according to an exemplary embodiment of the present invention is observed, and FIG. 2 is a scanning microscope image in which a network part between nanowires is observed. Specifically, the conductive network of FIG. 1 (and FIG. 2) was a transparent electrode sample (Sample 5 of Table 1) produced by using an Ag nanowire (diameter of 80 nm, aspect ratio of 1000) dispersion to apply the nanowire dispersion to a substrate (polyethylene terephthalate film) so that a nanowire fill factor is 9.5% to form a nanowire network, electrospinning 78 wt % of a silver nanoparticle (diameter of 20 nm) dispersion and a polyethylene oxide polymer solution on the nanowire network with a coaxial double nozzle to incorporate a fiber (metallic fiber diameter=1 μm) thereto so that a metallic fiber fill factor is 4.4%, performing washing with an organic solvent to remove a polyethylene oxide polymer sheath to produce a fiber-nanowire network, and then irradiating a white light (300-1000 nm) purse with a pulse width of 1500 μsec and an intensity of 1201.5 J/cm² three times. Here, the conductive network fill factor was 12.4%. The thus-produced transparent electrode had a light transmittance of 91% and a sheet resistance of 1.7 Ω/sq.

As seen from FIGS. 1 and 2, it was confirmed that a conductive fiber which was uniformly sintered without inner voids and surface cracks by a photonic sintering was produced, and it was found that a conductive network in which contact points between nanowires are fused was produced together with the sintering of the silver nanoparticles of the metallic fiber.

A transparent electrode (Sample 3 of Table 1) was produced in the same manner as the samples of FIGS. 1 and 2, except that incorporation was performed so that the nanowire fill factor when applying the first dispersion—the metallic fiber fill factor when electrospinning the second dispersion was 4.2%-8.9%. Here, the conductive network fill factor was 11.6%. The thus-produced transparent electrode had a light transmittance of 92% and a sheet resistance of 1.9 Ω/sq.

Similarly, the conductive network fill factor (Net. FF), the transmittance, and the sheet resistance of the transparent electrode which was produced with a difference of the nanowire fill factor (Wir. FF) when applying the first dispersion—the metallic fiber fill factor (Fib. FF) when electrospinning the second dispersion are summarized in Table 1.

TABLE 1

| | Sample 1 | Sample 2 | Sample 3 | Sample 4 | Sample 5 | Sample 6 | Sample 7 | Sample 8 | Sample 9 |
|---|---|---|---|---|---|---|---|---|---|
| Wir. FF (%) | 4.2 | 4.2 | 4.2 | 9.5 | 9.5 | 9.5 | 14.1 | 14.1 | 14.1 |
| Fib. FF (%) | 2.1 | 4.4 | 8.9 | 2.1 | 4.4 | 8.9 | 2.1 | 4.4 | 8.9 |
| Net. FF (%) | 4.8 | 8.9 | 11.6 | 10.1 | 12.4 | 16.9 | 14.7 | 17 | 21.5 |
| Transmittance (%) | 95 | 94 | 92 | 93 | 91 | 87 | 89 | 86 | 82 |
| Sheet resistance | 9.5 | 3.1 | 1.9 | 7.9 | 1.7 | 1.4 | 7.5 | 1.5 | 1.3 |
| (Ω/sq.) | | | | | | | | | |

As seen from Table 1, it was found that when the nanowire fill factor was in a range of 3 to 5% and the conductive fill factor was in a range of 8 to 10% and when the nanowire fill factor was in a range of 8 to 11% and the conductive fiber fill factor was in a range of 3 to 5%, the electrode may have both excellent transparency of a light transmittance of 91% or more and excellent electrical properties of a sheet resistance of 1.9 Ω/sq. or less.

FIG. 3 is a drawing illustrating a sheet resistance depending on the number of bends measured by performing a bending test 100,000 times with a curvature radius of 3 mm for the produced transparent electrode (Sample 5). As seen from FIG. 3, the sheet resistance after the bending test of 100,000 times was 1.76 Ω/sq., and it was found that a resistance increase rate [=(sheet resistance after bending test of 100,000 times−sheet resistance immediately after production)/(sheet resistance immediately after production)×100] was only 3.5%.

For comparison, a transparent electrode was produced in the same manner and with the same fill factor as Sample 5, except that the second dispersion was first electrospun and washing was performed with an organic solvent to produce a fiber network, and the first dispersion in which the nanowire was dispersed was applied to the fiber network and photonically sintered to produce the transparent electrode (Comparison Sample 1). The thus-produced transparent electrode (Comparison Sample 1) showed a similar light transmittance to Sample 5, but it was confirmed that the sheet resistance was increased to 2.0 Ω/sq. and greatly increased to 4.7 Ω/sq. when the electrode was subjected to a bending test 100,000 times with a curvature radius of 3 mm.

In addition, a transparent electrode was produced in the same manner and with the same fill factor as Sample 5, except that the second dispersion was first electrospun and washing was performed with an organic solvent to produce a fiber network, a heat treatment was performed at 200° C. for 2 hours to convert the metallic fiber network to the conductive fiber network, and then the first dispersion in which the nanowire was dispersed was applied to the conductive fiber network and photonically sintered to produce the transparent electrode (Comparison Sample 2). The thus-produced transparent electrode (Comparison Sample 2) showed a similar light transmittance to Sample 5, but it was confirmed that the sheet resistance was increased to 1.8 Ω/sq. and increased to 2.3 Ω/sq. when the electrode was subjected to a bending test 100,000 times with a curvature radius of 3 mm.

The transparent electrode according to the present invention is produced by forming a metal nanowire network, incorporating a metallic fiber into a network to form a fiber-nanowire network, and converting the metallic fiber into a conductive fiber by sintering and simultaneously performing fusion between the fiber and the nanowire and between the nanowires, thereby having a very high transparency and also significantly excellent electrical properties, and not causing deterioration of electrical properties even with repeated deformation while having excellent flexibility, and thus, is very appropriate for a foldable, flexible, or rollable device.

Hereinabove, although the present invention has been described by specific matters, limited exemplary embodiments, and drawings, they have been provided only for assisting the entire understanding of the present invention, and the present invention is not limited to the exemplary embodiments, and various modifications and changes may be made by those skilled in the art to which the present invention pertains from the description.

Therefore, the spirit of the present invention should not be limited to the above-described exemplary embodiments, and the following claims as well as all modified equally or equivalently to the claims are intended to fall within the scope and spirit of the invention.

What is claimed is:

1. A method of producing a transparent electrode, the method comprising:
a) applying a first dispersion containing a metal nanowire on a substrate to form a nanowire network;
b) electrospinning a second dispersion containing metal nanoparticles on the nanowire network to form a fiber-nanowire network in which a metallic fiber of the metal nanoparticles being agglomerated is incorporated into the nanowire network; and
c) sintering the fiber-nanowire network.

2. The method of producing a transparent electrode of claim 1, wherein the sintering is performed by a photonic sintering or a heat treatment.

3. The method of producing a transparent electrode of claim 1, wherein in step b), a coaxial double nozzle including an inner nozzle and an outer nozzle surrounding the inner nozzle is used at the time of electrospinning to spin the second dispersion through the inner nozzle and to spin a polymer solution through the outer nozzle, thereby forming a composite fiber in which the metallic fiber is wrapped by a polymer sheath.

4. The method of producing a transparent electrode of claim 3, further comprising: removing the polymer sheath from the composite fiber after the electrospinning of step b).

5. The method of producing a transparent electrode of claim 1, wherein the metallic fiber is converted into the conductive fiber by the sintering of step c) and fusion is performed between the nanowire and the fiber and between the nanowires of the fiber-nanowire network.

6. The method of producing a transparent electrode of claim 1, wherein in step a), a nanowire fill factor which is a ratio of an area covered by the metal nanowire is 3 to 11%, a fiber fill factor which is a ratio of an area covered by the metallic fiber is 3 to 10%, and a network fill factor which is a ratio of an area covered by the fiber-nanowire network is 9 to 13%, with respect to an area of the substrate.

7. The method of producing a transparent electrode of claim 2, wherein the heat treatment is performed at 150 to 250° C.

8. The method of producing a transparent electrode of claim 2, wherein the photonic sintering is performed by irradiation of a pulsed white light having an intensity of 800 to 1600 J/cm².

9. The method of producing a transparent electrode of claim 1, wherein a ratio of a diameter of the metallic fiber to a diameter of the metal nanowire is 10 to 1000.

10. The method of producing a transparent electrode of claim 1, wherein the metal nanowire and the metal nanoparticles of the metallic fiber include silver (Ag), gold (Au), aluminum (Al), copper (Cu), chromium (Cr), nickel (Ni), iron (Fe), or an alloy thereof, respectively.

11. A transparent electrode comprising:
a transparent film; and a conductive network, in which a metal nanowire and a metallic conductive fiber are mixed, positioned on the transparent film,
wherein a nanowire fill factor which is a ratio of an area covered by the metal nanowire is 3 to 11%, a fiber fill factor which is a ratio of an area covered by the metallic conductive fiber is 3 to 10%, and a conductive network fill factor which is a ratio of an area covered by the conductive network is 9 to 13%, in the transparent film.

12. The transparent electrode of claim 11, wherein the transparent electrode has a light transmittance of 90% or more and a sheet resistance of 1.9 Ω/sq. or less.

13. The transparent electrode of claim 11, wherein the transparent electrode has a sheet resistant increase rate of 5% or less, when a bending test is performed 100,000 times with a bending radius of 3 mm.

14. A device comprising the transparent electrode according to claim 11.
